(19) United States
(12) Patent Application Publication
(10) Pub. No.: US 2025/0269748 A1
(43) Pub. Date: Aug. 28, 2025

(54) HIGH-VOLTAGE DISTRIBUTION BOX AND CHARGING CONTROL METHOD THEREOF

(71) Applicants: Hyundai Motor Company, Seoul (KR); Kia Corporation, Seoul (KR)

(72) Inventors: Seung Woo Kim, Hwaseong-Si (KR); Dae Hyun Kim, Hwaseong-Si (KR); Dong Geon Lee, Hwaseong-Si (KR)

(21) Appl. No.: 18/966,398

(22) Filed: Dec. 3, 2024

(30) Foreign Application Priority Data
Feb. 23, 2024 (KR) 10-2024-0026670

(51) Int. Cl. B60L 53/302; B60L 53/10; B60L 58/12

(52) U.S. Cl. CPC B60L 53/302; B60L 53/11; B60L 58/12

(57) ABSTRACT

The present disclosure relates to a high-voltage distribution circuit and a charging control method to reduce heat generation. The high-voltage distribution circuit provides practical effects such as forming a water cooling structure simply and compactly by applying a DC inlet and a water cooling circuit together in a housing, and improving cooling efficiency and charging efficiency of fast charging at the same time.

### CROSS-REFERENCE TO RELATED APPLICATION

The present application claims the benefit of priority to Korean Patent Application No. P2024-0026670, filed in the Korean Intellectual Property Office on Feb. 23, 2024, the entire contents of which is incorporated herein for all purposes by this reference.

### TECHNICAL FIELD

The present disclosure relates to a high-voltage distribution circuit and a charging control method to reduce heat generation.

### BACKGROUND

The matters described in this Background section are only for enhancement of understanding of the background of the disclosure, and should not be taken as acknowledgment that they correspond to prior art already known to those skilled in the art.

Due to increasing battery capacity of electronic vehicles, it may take a long time to charge a battery. To solve this problem, fast chargers that supply relatively high current from a charger and rapidly charge the battery are considered.

### SUMMARY

According to the present disclosure, an apparatus for distributing voltage, the apparatus may comprise, a housing may comprise a plurality of side walls and an opening, a cover configured to cover the opening, a direct current (DC) inlet placed in the housing, wherein the DC inlet may comprise a positive terminal and a negative terminal, each terminal, of the positive terminal and the negative terminal, being exposed to an outside of the housing through at least one of the plurality of side walls, at least one connector placed on at least one of the plurality of side walls, a relay switch placed inside the housing, a bus bar configured to couple the DC inlet with the relay switch, a fuse configured to couple the relay switch with the at least one connector, a water cooling circuit placed inside the housing, the water cooling circuit may comprise, a cooling passage, an inlet for supplying a coolant to the cooling passage, and an outlet for discharging the coolant from the cooling passage, and an alternate current (AC) inlet placed in the cover, the AC inlet may comprise an AC terminal circuit and a communication line.

The apparatus, wherein at least one side wall of the plurality of side walls comprises, a first through hole into which the positive terminal is inserted, and a plurality of second through holes into which the negative terminal is inserted.

The apparatus, wherein the plurality of second through holes comprise, a second-first through hole horizontally spaced apart from the first through hole, and a second-second through hole horizontally spaced apart from the second-first through hole.

The apparatus, wherein the bus bar comprises, a first bus bar connected to the positive terminal, and a second bus bar connected to the negative terminal, wherein the second bus bar comprises, a first connection circuit placed to correspond to the second-first through hole, and a second connection circuit placed to correspond to the second-second through hole, and wherein the negative terminal is connected to either the first connection circuit or the second connection circuit, based on whether the negative terminal is placed through the second-first through hole or the second-second through hole, respectively.

According to the present disclosure, a method for controlling charging of a voltage distribution circuit, the method may comprise, setting a charging current for charging a battery, determining a heat generation amount associated with the charging current, increasing the charging current based on a charging time period not being satisfied and based on the heat generation amount being a threshold amount or below the threshold amount, charging the battery based on the heat generation amount reaching above the threshold amount, determining whether a change of setting of the charging current occurs based on a state of charge (SOC) of the battery not being satisfied, measuring a temperature of a bus bar based on the change of setting of the charging current not occurring, updating a cooling parameter based on the measured temperature reaching a threshold temperature, and selecting, based on the updated cooling parameter, one of increasing cooling of the bus bar or decreasing the charging current.

The method, wherein the charging the battery may comprise charging the battery before the measured temperature reaching the threshold temperature.

The method, wherein the selecting may comprise proceeding with the charging by increasing the cooling based on a first power consumption associated with the increasing the cooling being smaller than a second power consumption associated with the decreasing the charging current.

The method, wherein the selecting may comprise proceeding with the charging by applying the decreasing the charging current based on a first power consumption associated with the increasing the cooling being greater than a second power consumption associated with the decreasing the charging current.

The method, wherein the determining the heat generation amount may comprise determining the heat generation amount based on the charging current, a resistance of the bus bar, and a duration of current flow.

The method, wherein the determining the heat generation amount may comprise further, predicting a temperature change of the bus bar based on a mass of the bus bar and a heat capacity of the bus bar.

According to the present disclosure, a method for controlling charging of a voltage distribution circuit, the method may comprise, setting a charging current for charging a battery, setting a maximum charging current for charging the battery, proceeding with charging the battery for a first cycle, determining whether a state of charge (SOC) of the battery is satisfied, determining whether a change of setting of the charging current occurs based on the SOC of the battery not being satisfied, setting a cooling parameter based on the change of setting of the charging current occurring at a first time point, and measuring a temperature of a bus bar based on the change of setting of the charging current not occurring at a second time point, and proceeding with charging the battery for a second cycle based on the measured temperature of the bus bar not reaching a threshold temperature at a third time point, and proceeding with charging the battery for a third cycle by updating the cooling parameter based on the measured temperature reaching the threshold temperature at a fourth time point.

The method, wherein the setting the cooling parameter may comprise controlling to stop cooling of the bus bar.

The method, wherein the updating the cooling parameter may comprise controlling to increase cooling of the bus bar.

The method, may further comprise completing the charging after the SOC of the battery transitions from not being satisfied to being satisfied.

The method, wherein the proceeding with charging the battery for the third cycle may comprise increasing, based on the updated cooling parameter, cooling of the bus bar or decreasing the charging current.

The method, wherein the proceeding with charging the battery for the third cycle may comprise increasing cooling of the bus bar based on a first power consumption associated with the increasing the cooling being smaller than a second power consumption associated with decreasing the charging current.

The method, wherein the proceeding with charging the battery for the third cycle may comprise decreasing the charging current based on a first power consumption associated with increasing cooling of the bus bar being greater than a second power consumption associated with the decreasing the charging current.

The method, may further comprise, determining a heat generation amount associated with the charging current.

The method, may further comprise, increasing the charging current based on a charging time period not being satisfied and the heat generation amount being a threshold amount or below the threshold amount.

The method, wherein the determining the heat generation amount may comprise determining the heat generation amount based on the charging current, a resistance of the bus bar, and a duration of current flow.

### BRIEF DESCRIPTION OF DRAWINGS

FIG. 1 shows an example of a high-voltage charging structure according to an example of the present disclosure;

FIG. 2 shows an example of DC inlet and AC inlet that are integrally formed by injection molding according to an example of the present disclosure;

FIG. 3 and FIG. 4 show examples of a high-voltage distribution box according to an example of the present disclosure;

FIG. 5 shows an example of a process that prioritizes minimum power consumption in a charging control method of a high-voltage distribution box according to an example of the present disclosure;

FIG. 6 shows an example of a charging profile in a charging control method of a high-voltage distribution box according to an example of the present disclosure;

FIG. 7 shows an example of a change of consumption power in a water cooling increase or a changing current in a charging current decrease in a charging control method of a high-voltage distribution box according to an example of the present disclosure;

FIG. 8 shows an example of a consumption current of a vehicle in a charging current decrease and consumption power of a vehicle in a cooling performance increase in a charging control method of a high-voltage distribution box according to an example of the present disclosure; and

FIG. 9 shows an example of a process that prioritizes a charging speed in a charging control method of a high-voltage distribution box according to an example of the present disclosure.

### DETAILED DESCRIPTION

While examples are described with reference to the accompanying drawings, it should be understood that various changes and modifications may be made in the disclosure. Further, it should be understood that the disclosure is not limited to the specific examples thereof, and various changes, equivalences, and substitutions may be made without departing from the scope and spirit of the disclosure.

Terms containing ordinal numbers, such as “first”, “second”, etc., may be used to describe various components, but the components are not limited by the terms. These terms may be used only in a nominal sense to differentiate one component from another component, and their mutual sequential meaning will be understood through the context of the corresponding description, not through such terms.

The term “and/or” is used to include all instances of any combination of multiple items being the subject. For example, “A and/or B” includes all three cases: “A”, “B”, and “A and B”.

When a component is used to be “coupled” or “connected” to another component, it will be understood that the component may be either connected directly to another component or connected indirectly via another medium. It is also noted that in this specification, “connected/coupled” refers to one component not only directly coupling another component but also indirectly coupling another component through an intermediate component. On the other hand, “directly connected/directly coupled” refers to one component directly coupling another component without an intermediate component.

It will also be understood that when a layer (film), a region, a pattern, or a structure is referred to as being “on” another layer (film), region, pad, or pattern, it may be directly on the other layer or intervening layers may also be present. Further, it will be understood that when a layer is referred to as being “on/under” or “under/on”, it may be shown in the drawings for convenience, and is only used to indicate the relative positional relationship between components. It should not be understood to limit the positions of actual components. For example, “on B” simply indicates that B is shown above A in the drawing, unless otherwise stated or in the case where A should be placed above B due to the nature of A or B. In actual products, etc. B may be located under A or B and A may be placed side to side.

In addition, the thickness or size of each layer (film), region, pattern or structure in the drawings may be changed for clarity and convenience of explanation, and it may not entirely reflect the actual size.

The terms in the present application are used to describe an example and do not intend to restrict and/or limit the present disclosure. Singular forms are intended to include plural forms unless the context clearly indicates otherwise. According to an example of the present disclosure, terms such as “comprise” or “consist of” are used to designate presence of characteristics, numbers, steps, operations, elements, components or a combination thereof, and do not foreclose the presence or possibility of addition of one or more other characteristics, numbers, steps, operations, elements, components or a combination thereof.

Specifically, for purposes of this application and the claims, using the exemplary phrase “at least one of: A; B; or C” or “at least one of A, B, or C,” the phrase means “at least one A, or at least one B, or at least one C, or any combination of at least one A, at least one B, and at least one C. Further, exemplary phrases, such as “A, B, and C”, “A, B, or C”, “at least one of A, B, and C”, “at least one of A, B, or C”, etc. as used herein may mean each listed item or all possible combinations of the listed items. For example, “at least one of A or B” may refer to (1) at least one A; (2) at least one B; or (3) at least one A and at least one B.

Unless otherwise defined, all terms used in the example of the present disclosure including technical or scientific terms, have the same meaning as generally understood by an ordinary person skilled in the technical field to which the present disclosure pertains. Terms defined in commonly used dictionaries will be interpreted as having a meaning consistent with the meaning in the context of the related technology, and unless clearly defined in this application, should not be interpreted in an ideal or excessively formal sense.

An example of the present disclosure will be described in detail with reference to the attached drawings, but identical or corresponding components will be assigned the same reference numbers regardless of the reference numerals, and duplicate descriptions thereof will be omitted.

According to the present disclosure, an inlet and high-voltage (HV) circuit is integrated into a single unit, reducing system size, weight, material costs, and complexity while enhancing heat management through internal cooling, avoiding the need for external cable cooling. Unlike other designs, it separates DC and AC terminals, placing a high-heat DC terminal within a cooling box for better dissipation, thereby improving charging efficiency and reliability. Further, a modular, detachable DC terminal structure supports compatibility with various charging standards and communication protocols, enhancing adaptability across different vehicle models. An advanced thermal control mechanism dynamically manages power and temperature during charging, allowing enhanced speed or energy efficiency based on preferences, and ensuring a system maintains safe temperatures by adjusting cooling power based on charging current, time, and battery state-of-charge. Such design improves high-capacity charging by enhancing thermal management, simplifying components, and increasing versatility across standards.

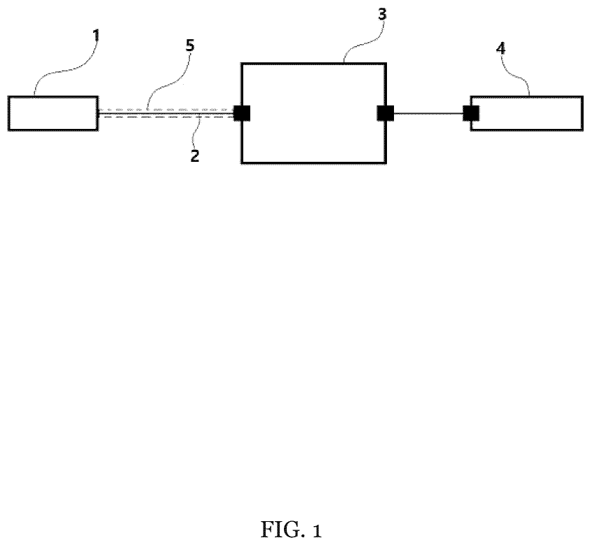

Referring to FIG. 1, an inlet cable assembly may be configured to electrically connect a charging inlet 1 and a high-voltage battery 4, including an inlet 1, a cable 2, and a connector, whereby a connector is coupled to a circuit (e.g., a high-voltage distribution box 3).

A high-capacity charging may be a high current of 1,000˜3,000 A, which is far beyond an average charging current of 200˜400 A, and a cable water cooling area 5 that cools the heat generated from the cable 2 of the inlet 1 during charging may be applied.

The cable water cooling area 5 applied to the cable 2 of the inlet 1 may complicate the structure of the cable 2, and increase material costs and weight of the cable. Also, safety problems due to overheating may exist.

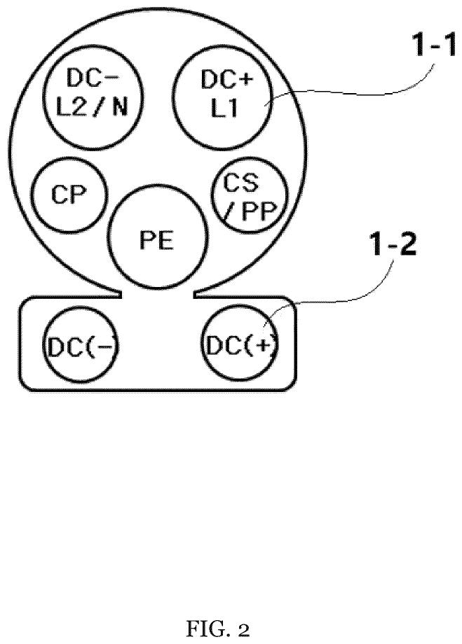

Specifically, as shown in FIG. 2, the inlet 1 may include an AC terminal 1-1 and a DC terminal 1-2. The AC terminal 1-1 and DC terminal 1-2 may be integrally manufactured by injection molding.

In the case of the inlet 1 in which the AC terminal 1-1 and the DC terminal 1-2 are integrally manufactured by injection molding, unlike the AC terminal 1-1 connected to an AC power line and a communication line, overheating may occur in the DC terminal 1-2 due to a large current flow.

However, the structural problem lies in that a water cooling structure for heating the DC terminal 1-2 may not be applied since the inlet 1 is integrally manufactured by injection molding.

Specifically, the inlet in which the AC terminal 1-1 and the DC terminal 1-2 are integrally manufactured by injection molding may be custom-designed for a specific communication protocol, and may not be compatible with other communication protocols.

According to an example of the present disclosure, a high-voltage distribution box (e.g., circuit) may include a housing 100, a housing cover 110, a DC inlet 160, a connector 190, a relay switch 200, a bus bar, a fuse 250, a water cooling module 280, and an AC inlet 260.

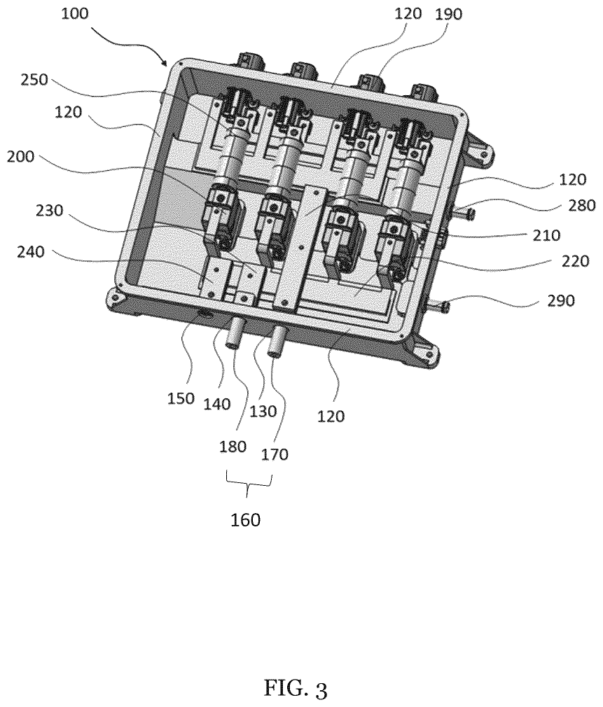

The housing 100 may include an open-top surface and a plurality of side walls 120. According to an example, the housing 100 may include four (4) side walls 120 as shown in FIG. 3.

The housing cover 110 may cover the top surface of the housing 100. The housing cover 110 may be placed on the top of four (4) of the side walls 120.

The DC inlet 160 may be placed in the housing 100, including a +terminal 170 and a −terminal 180. The ends of the +terminal 170 and the −terminal 180 may penetrate at least one of the plurality of side walls 120 to be exposed to the outside.

A first through hole 130 into which the +terminal 170 is inserted may be formed on at least one of the four (4) side walls 120 described above, and a plurality of second through holes into which the −terminal 180 is inserted may be formed.

The plurality of second-through holes may include a 2-1 through hole 140 formed to be spaced apart in a horizontal direction, and a 2-2 through hole 150 formed to be spaced apart in a horizontal direction.

The −terminal 180 of the DC inlet 160 may be selectively inserted into the 2-1 through hole 140 and the 2-2 through hole 150. In the DC inlet 160, the spacing between the +terminal 70 and the −terminal 180 may be different depending on national standards. In the DC inlet 160, the problem lies in that the spacing between the +terminal 170 and the −terminal 180 are different according to national standards, and the DC inlet 160 may be manufactured by different injection molding for each country. The present disclosure aims to share without having to manufacture the DC inlet 160 with different standards by inserting the +terminal 170 to the first through hole 130, and selectively inserting the −terminal 180 to the 2-1 terminal or the 2-2 terminal.

A least one connector 190 may be placed on at least one side wall 120 of a plurality of side walls 120. According to an example, the connector 190 may include a plurality of connectors 190. The number of connectors 190 may be four (4) or more depending on the number of bus bars and the number of battery modules described below.

The relay switch may be placed inside the housing 100.

The bus bar may connect the DC inlet 160 and the relay switch 200.

The bus bar may include a first bus bar 210 connected to a +electrode, and a second bus bar 220 connected to an −electrode.

The first bus bar 210 may be connected to the +terminal 170.

The second bus bar 220 may include a first connection unit 230 connected when the −terminal 180 is placed in the 2-1 through hole 140, and a second connection unit 240 connected when the −terminal 180 is placed in the 2-2 through hole 150.

The fuse 250 may connect the relay switch 200 and the connector 190.

The fuse 250 may be cut off when an overcurrent flows in the bus bar and may serve to protect a battery module.

The water cooling module 280 may include a cooling passage (not shown) inside the housing 100. The cooling passage may be placed on the bottom of the housing 100. The cooling passage may be placed on the entire bottom or a part of the bottom of the housing 100. The cooling passage may be integrally formed with the housing 100. The cooling passage may include an inlet 280 and an outlet 290.

The inlet 280 may supply a coolant to a cooling passage, and the outlet 290 may discharge a coolant that circulates the cooling passage to the outside.

The AC inlet 260 may be placed on the housing cover 110, including an AC terminal unit (not shown), and a communication line (not shown).

Referring to FIG. 2, the layout of the AC terminal unit and the communication line of the AC inlet 260 will be shown.

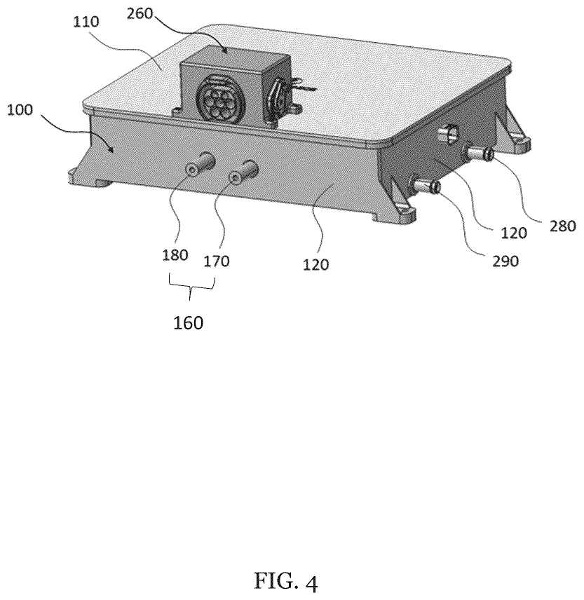

Referring to FIG. 4, the AC inlet 260 may be placed on the top of the housing cover 110, specifically, on the top of the +terminal 170 and the −terminal 180 of the DC inlet 160 provided in the housing 100.

When the housing cover 110 is connected to the housing 100, the AC inlet 260 may be placed on the top of the housing cover 110, which is above the +terminal 170 and the −terminal 180 of the DC inlet 160.

According to an example, a control algorithm that prioritizes minimum power consumption in a charging control method of a high-voltage distribution circuit will be described.

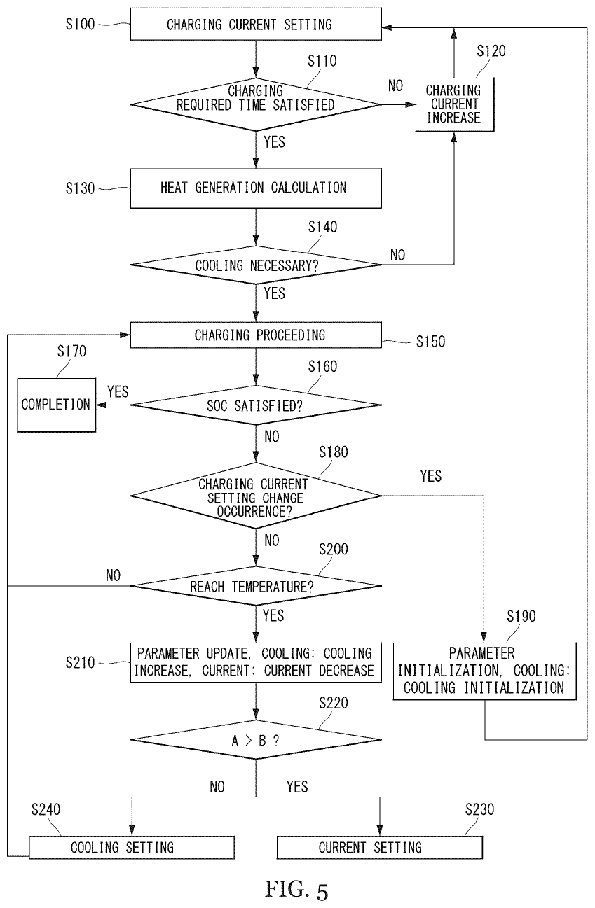

For convenience, FIG. 5 is described by way of an example in which the steps are performed by a processor (e.g., control circuitry). One, some, or all steps of FIG. 5, or portions thereof, may be performed by one or more other circuits. One or some, steps of FIG. 5 may be omitted, performed in other orders, and/or otherwise modified, and/or one or more additional steps may be added. Referring to FIG. 5, the control algorithm that prioritizes minimum power consumption may set a charging current at step S100. The minimum charging current may be arbitrarily set by a user. For example, a charging current may be arbitrarily set to be low by a user if it is available.

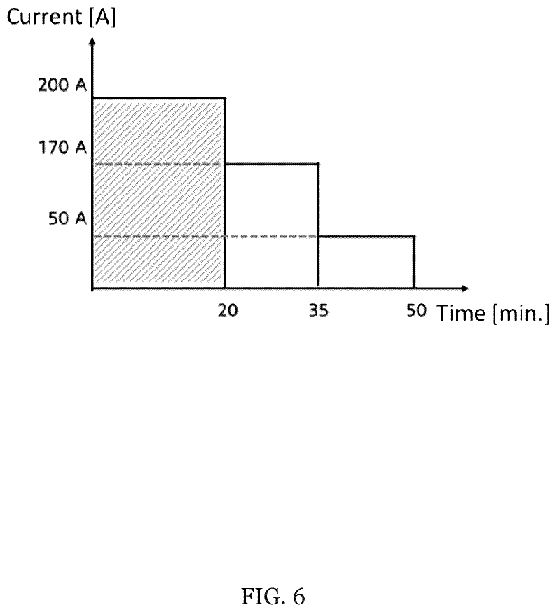

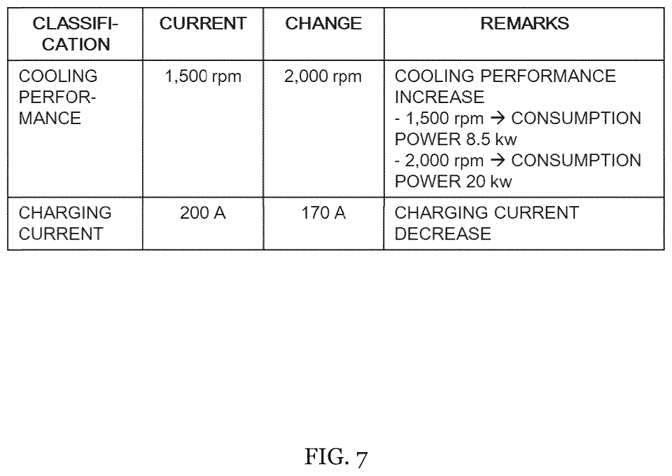

When the user sets a charging current arbitrarily, a charging profile may be derived as shown in FIG. 6. It may be determined whether the charge profile shown in FIG. 6 satisfies the charging time required by a user at step S110. For example, when the user wants the SOC to be charged 100% within three hours, a charging current that completes charging within three hours may be set. In the control algorithm, an initial charging current may be determined depending on the battery status (SOC, etc.), and when the charging current is determined, a charging required time may be determined according to the charging profile.

If the charging required time of the user is not satisfied, the charging current may be increased in priority over the charging that consumes minimum power at step S120 to satisfy the charging required time of the user. The condition to satisfy the charging required time of the user may be given priority over the minimum power consumption condition.

When the setting of a charging current is set to be lowered due to an increase in battery SOC, the current may not exceed the decreased current setting value. In this case, the battery may be switched to a cooling mode to cool the bus bar.

If it is determined that the charging required time of the user is satisfied, the heat generation amount when a current suitable for the charging required time flows may be determined at step S130.

The heat generation amount may be the heat generated by a charging current flow of the bus bar placed in the high-voltage circuit. The heat generation amount may be determined by a specific current amount and a current flow time based on the charging profile information shown in FIG. 6.

The calculation of the heat generation amount will be performed based on [Equation A].

$$Q = {I}^{2} * R * t \qquad [ Equation A ]$$

Q=J (heat generation amount), I=A (current), R=Ω (bus bar resistance), t=s (time)

Also, how high the temperature rises will be predicted by using Equation 2 below, which is the thermal energy formula.

$$Δ T = \frac{Q}{m \cdot {C}_{p}} \qquad [ Equation B ]$$

It may be possible to predict how high the temperature of the bus bar rises through [Equation A] and [Equation B] above.

When the heat generation amount is determined, it may be determined whether the bus bar needs cooling at step S140. When the heat generation amount is determined, the heat generation amount or the temperature rise of the bus bar may be predicted. Therefore, it may be possible to determine whether to perform cooling depending on whether the temperature rise of the bus bar, or the +terminal 170, the −terminal 180 of the DC inlet 160 reaches a limited value during the charging current flow.

For example, when an initial charging current is set to be 200 A, the temperature of the bus bar may be expected to rise at 135° C., exceeding the temperature rise limit value of 100° C., so that it may be determined that cooling is necessary.

When an initial charging current is set to be 170 A, the temperature of the bus bar may be expected to rise at 95° C., and it may not reach the temperature rise limit value of 100° C., so that it may be determined that cooling is not necessary.

When the cooling is not necessary, it may be desirable to increase a charging current since it is possible to minimize the vehicle consumption power by shortening the charging time. When the cooling is necessary since the power in a vehicle is consumed during charging, it may require a control voltage (12V) supply that is operated during charging, and a high-voltage (400V or more) for the motor driving of a pump to circulate a coolant.

If it is determined that the cooling is not necessary, only the control voltage (12V) supply operated during charging may be necessary, thereby consuming less power.

If it is determined whether cooling is necessary, charging a battery module of a vehicle may proceed at step S150. The charging may proceed by setting the maximum current that satisfies the charging required time of the user without cooling.

The charging may be completed at step S170 if the SOC of the battery is satisfied at step S160, and if the SOC is not satisfied at step 160, it may be determined whether the change of setting of the charging current occurs at step S180.

As the SOC of the battery increases, the charging current may decrease, and it may be determined that the change of setting of the charging current may occur. If the charging current decreases, the temperature of the bus bar may decrease. Therefore, the change of setting of the charging current according to the SOC increase may occur, regardless of temperature control, so that it may be possible to stop unnecessary cooling according to the charging current decrease by initializing a cooling parameter or reduce a cooling function by removing a cooling pump motor.

If it is determined that the change of setting of the charging current may not occur, it may be determined whether the temperature of bus bar reaches at a preset temperature at step S200. The preset temperature may be a rise limit temperature described below.

The temperature may be sensed and measured by a temperature sensor placed in the bus bar in the high-voltage circuit or in the +terminal 170 and the −terminal 180 of the DC inlet 160. The temperature sensor may sense whether the temperature reaches, for example, a limit temperature (e.g., a rise limit temperature of 100° C.).

If the measured temperature fails to reach the preset temperature, charging the battery may be performed at step S150. If the measured temperature reaches the preset temperature, the situation may be determined to suppress temperature rise and the cooling parameter may be updated at step S210.

The cooling parameter update may include applying a temperature rise suppression control logic to prevent temperature rise through a current flow, and the temperature rise suppression control logic may be one of first and second logics described below.

The first logic may be a logic that increases a cooling function and an RPM of a motor for driving a pump to increase the amount of coolant.

The second logic may be a logic that decreases a charging current to reduce the amount of heat generation by a current flow.

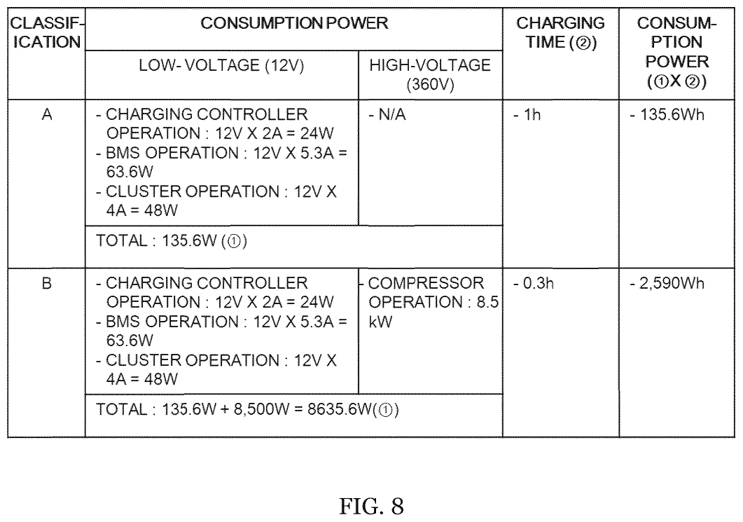

For example, if the situation is determined to suppress the temperature rise, as shown in FIG. 8, a current cooling performance figure may be increased, and the charging current setting may be decreased.

Accordingly, charging may be performed by updating a cooling parameter based on minimum power consumption by calculating vehicle power consumption (A) during a charging current decrease and vehicle power consumption (B) during a cooling performance increase, and comparing the vehicle power consumption (A) during a charging current decrease and the vehicle power consumption (B) during a cooling performance increase.

For example, as shown in the table in FIG. 8, if the vehicle power consumption (A) during the charging current decrease is lower than the vehicle power consumption (B) during the cooling performance increase at step S220, it may be set to change a charging current at step S230. On the other hand, if the vehicle power consumption (A) during the charging current decrease is greater than the vehicle power consumption (B) during the cooling performance increase at step S220, the cooling may be set to increase without changing the charging current at step S240.

According to an example, a control algorithm that prioritizes a charging speed in a charging control method of a high-voltage distribution circuit will be described.

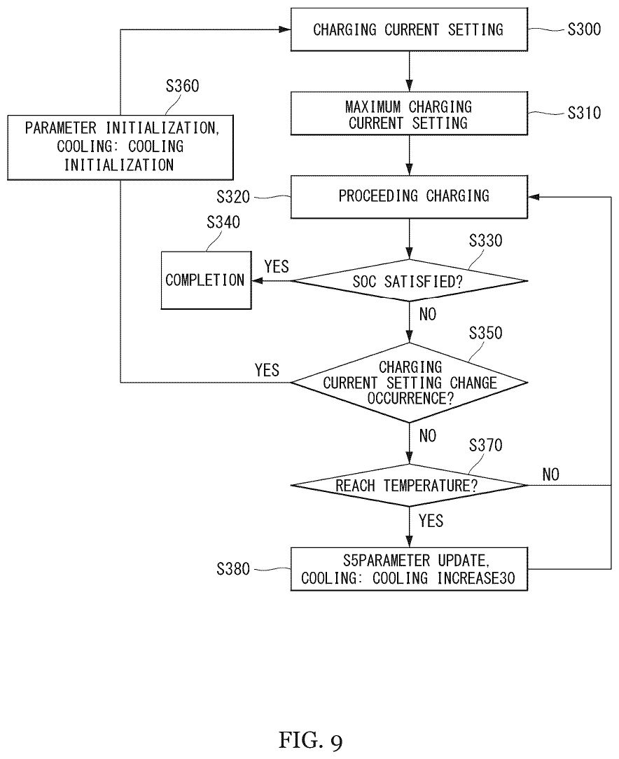

For convenience, FIG. 9 is described by way of an example in which the steps are performed by a processor (e.g., control circuitry). One, some, or all steps of FIG. 9, or portions thereof, may be performed by one or more other circuits. One or some, steps of FIG. 9 may be omitted, performed in other orders, and/or otherwise modified, and/or one or more additional steps may be added. Referring to FIG. 9, the control algorithm that prioritizes a charging speed may set a charging current at step S300. The charging current may be arbitrarily set by a user at step S310.

When the charging current is set, the vehicle may have a priority over a charging speed, so the maximum charging current may be set even if the user arbitrarily sets the charging current at step S310.

When the maximum charging current is set, charging the battery module of a vehicle may be performed at step S320. If the SOC of the battery is satisfied at step S330, the charging may be terminated at step S340, and if the SOC is not satisfied at step S330, it may be identified whether the change of setting of the charging current occurs at step S350. The charging current of the battery may decrease as the SOC increases, and this indicates that the change of setting of the charging current occurs. As the charging current decreases, the temperature of the bus bar may be decreased, and thus the change of setting of the charging current may occur due to an increase in the SOC regardless of temperature control. Therefore, it may be possible to stop unnecessary cooling due to a decrease in the charging current by initializing a cooling parameter at step S360 or reduce a cooling performance by controlling a cooling pump motor.

If it is determined that the change of setting of the charging current may not occur, it may be determined whether a measured temperature of the bus bar reaches a preset temperature at step S370. The preset temperature may be a rise limit temperature described below.

A temperature may be sensed and measured by a temperature sensor provided in the bus bar inside the high-voltage circuit or in the +terminal 170 and −the terminal 180 of the DC inlet 160. The temperature sensor, for example, may sense whether the temperature reaches a limit temperature, for example, (e.g., setting a rise limit temperature of 100° C.).

If the measured temperature fails to reach the preset temperature, the charging of the battery may be performed. If the measured temperature reaches the preset temperature, the situation may be determined to suppress temperature rise and a cooling parameter may be updated at step S380.

The cooling parameter update may include applying a temperature rise suppression control logic to prevent temperature rise by a current flow, and the first logic may be applied to the temperature rise suppression control logic.

The first logic may be a logic that increases a cooling performance and an RPM of a motor for driving a pump to increase the amount of coolant.

If the cooling parameter is updated using the first logic that increases the cooling, the cooling performance may increase to maximize the charging current, thereby rapidly charging the battery.

In order to solve the problems of the prior art described above, the present disclosure aims to provide a high-voltage distribution circuit comprising a DC inlet provided in the housing to allow space adjustment between +terminal and −terminal to correspond to various standards, and a water-cooling module placed in the housing to which the DC inlet is applied to cool heat generation that occurs while the DC inlet is charged.

The present disclosure aims to provide a charging control method of a high-voltage distribution circuit configured to control a charging current, a temperature, and a flow rate of a coolant of a water-cooling module in a charging speed mode or in a power consumption efficiency mode, and control the charging heat temperature of the DC inlet at a predetermined temperature or below.

An example of the present disclosure is related to providing a high-voltage distribution circuit, including a housing including a plurality of side walls and an opening, a housing cover configured to cover the opening, a DC inlet placed in the housing and including a plus (+) terminal and a minus (−) terminal exposed to an outside of the housing through at least one of the plurality of side walls, at least one connector placed on at least one of the plurality of side walls, a relay switch placed inside the housing, a bus bar configured to connect the DC inlet and the relay switch, a fuse configured to connect the relay switch and the connector, a water cooling module including a cooling passage placed inside the housing, an inlet for supplying a coolant to the cooling passage, and an outlet for discharging the coolant from the cooling passage, and an AC inlet placed in the housing cover, the AC inlet including an AC terminal unit and a communication line.

The side wall may include a first through hole into which the plus terminal is inserted, and a plurality of second through holes into which the minus terminal is inserted.

The plurality of second through holes may include a second-first through hole horizontally spaced apart from the first through hole, and a second-second through hole horizontally spaced apart from the second-first through hole.

The bus bar may include a first bus bar connected to the plus terminal, and a second bus bar connected to the minus terminal, wherein the second bus bar comprises a first connection unit placed correspondingly to the second-first through hole, and a second connection unit placed correspondingly to the second-second through hole, and wherein the minus terminal is connected to the first connection unit or the second connection unit according to being placed through the second-first through hole or the second-second through hole.

An example of the present disclosure is related to providing a charging control method of a high-voltage distribution circuit, the method including setting a charging current for charging a battery, increasing the charging current in response to a charging required time period not being satisfied, and determining a heat generation amount in response to the charging required time period being satisfied, increasing the charging current in response to the heat generation amount being a predetermined heat generation amount or below, and proceeding to charge the battery in response to the heat generation amount being above the predetermined heat generation amount, terminating the charging of the battery in response to a SOC of the battery being satisfied, and determining whether a change of setting of the charging current occurs in response to the SOC of the battery not being satisfied, initializing a cooling parameter in response to the change of setting of the charging current occurring, and measuring a temperature of a bus bar in response to the change of setting of the charging current not occurring, proceeding to charge the battery in response to the measured temperature of the bus bar not reaching a predetermined temperature, and updating the cooling parameter in response to the measured temperature reaching the predetermined temperature, and selecting one of a cooling increase of the bus bar or a decrease of the charging current based on the updating of the cooling parameter.

The initializing of the cooling parameter may include controlling to stop cooling of the bus bar.

Selecting one of the cooling increase of the bus bar or the decrease of the charging current may include proceeding with the charging by applying the cooling increase in response to power consumption during the cooling increase being smaller than power consumption during the decrease of the charging current.

Selecting one of the cooling increase of the bus bar or the decrease of the charging current may include proceeding with the charging by applying the decrease of the charging current in response to power consumption during the cooling increase being greater than power consumption during the decrease of the charging current.

The determining of the heat generation amount may be performed by using [Equation A].

$$Q = I 2 * R * t \qquad [ Equation A ]$$

Q=J (Heat Generation Amount), I=A (Current), R=Ω (Bus bar Resistance), t=s (Time)

The determining of the heat generation amount may further include predicting a temperature rise of the bus bar, wherein the predicting is performed by using [Equation B].

$$Δ T = \frac{Q}{m \cdot {C}_{p}} \qquad [ Equation B ]$$

ΔT: a change in temperature (e.g., temperature rise) of the bus bar.
Q: a heat generation amount (energy in joules) generated by the bus bar.
m: mass of the bus bar.
Cₚ: a specific heat capacity of the bus bar material, which indicates an amount of heat required to raise the temperature of one unit of mass of the material by one degree Celsius.

An example of the present disclosure is related to providing a charging control method of a high-voltage distribution circuit, the method including setting a charging current for charging a battery, setting a maximum charging current for charging the battery, proceeding with charging the battery, determining whether a SOC of the battery is satisfied, completing the charging in response to the SOC of the battery being satisfied, and determining whether a change of setting of the charging current occurs in response to the SOC of the battery not being satisfied, initializing a cooling parameter in response to the change of setting of the charging current occurring, and measuring a temperature of a bus bar in response to the change of setting of the charging current not occurring, and proceeding with charging the battery in response to the measured temperature of the bus bar not reaching a predetermined temperature, and proceeding with charging the battery by updating the cooling parameter in response to the measured temperature reaching the predetermined temperature.

The initializing of the cooling parameter may include controlling to stop cooling of the bus bar.

The updating of the cooling parameter may include controlling to increase cooling of the bus bar.

The high-voltage distribution circuit according to the present disclosure may provide practical effects such as forming a water cooling structure simply and compactly by applying a DC inlet and a water cooling module together in a housing, and improving cooling efficiency and charging efficiency of fast charging at the same time.

Also, the present disclosure achieves the effect of reducing heat loss by controlling a charging current, a temperature, and a fluid rate of a coolant of a water-cooling module in a charging speed mode or a power consumption efficiency mode, and controlling a charging heating temperature of a DC inlet below a predetermined temperature.

The effects obtained from the present disclosure are not limited to the effects described above, and other effects not mentioned may be clearly understood by those skilled in the art from the description below.

Although the above description focuses on examples, this is only an example and does not limit the present disclosure, and those skilled in the art will understand that various variations and applications are possible without departing from the substantial characteristics of an example of the present disclosure. For example, in the example, each component may be modified and implemented. The variations and differences in application should be construed as being included in the scope of the present disclosure as defined in the appended claims.

What is claimed is:

1. An apparatus for distributing voltage, the apparatus comprising:
a housing comprising a plurality of side walls and an opening;
a cover configured to cover the opening;
a direct current (DC) inlet placed in the housing, wherein the DC inlet comprises a positive terminal and a negative terminal, each terminal, of the positive terminal and the negative terminal, being exposed to an outside of the housing through at least one of the plurality of side walls;
at least one connector placed on at least one of the plurality of side walls;
a relay switch placed inside the housing;
a bus bar configured to couple the DC inlet with the relay switch;
a fuse configured to couple the relay switch with the at least one connector;
a water cooling circuit placed inside the housing, the water cooling circuit comprising:
a cooling passage,
an inlet for supplying a coolant to the cooling passage, and
an outlet for discharging the coolant from the cooling passage; and
an alternate current (AC) inlet placed in the cover, the AC inlet comprising an AC terminal circuit and a communication line.

2. The apparatus of claim 1, wherein at least one side wall of the plurality of side walls comprises:
a first through hole into which the positive terminal is inserted, and
a plurality of second through holes into which the negative terminal is inserted.

3. The apparatus of claim 2, wherein the plurality of second through holes comprise:
a second-first through hole horizontally spaced apart from the first through hole; and
a second-second through hole horizontally spaced apart from the second-first through hole.

4. The apparatus of claim 3, wherein the bus bar comprises,
a first bus bar connected to the positive terminal; and
a second bus bar connected to the negative terminal,
wherein the second bus bar comprises,
a first connection circuit placed to correspond to the second-first through hole; and
a second connection circuit placed to correspond to the second-second through hole, and
wherein the negative terminal is connected to either the first connection circuit or the second connection circuit, based on whether the negative terminal is placed through the second-first through hole or the second-second through hole, respectively.

5. A method for controlling charging of a voltage distribution circuit, the method comprising:
setting a charging current for charging a battery;
determining a heat generation amount associated with the charging current;
increasing the charging current based on a charging time period not being satisfied and based on the heat generation amount being a threshold amount or below the threshold amount;
charging the battery based on the heat generation amount reaching above the threshold amount;
determining whether a change of setting of the charging current occurs based on a state of charge (SOC) of the battery not being satisfied;
measuring a temperature of a bus bar based on the change of setting of the charging current not occurring;
updating a cooling parameter based on the measured temperature reaching a threshold temperature; and
selecting, based on the updated cooling parameter, one of increasing cooling of the bus bar or decreasing the charging current.

6. The method as claimed in claim 5, wherein the charging the battery comprises charging the battery before the measured temperature reaching the threshold temperature.

7. The method as claimed in claim 5, wherein the selecting comprises proceeding with the charging by increasing the cooling based on a first power consumption associated with the increasing the cooling being smaller than a second power consumption associated with the decreasing the charging current.

8. The method as claimed in claim 5, wherein the selecting comprises proceeding with the charging by applying the decreasing the charging current based on a first power consumption associated with the increasing the cooling being greater than a second power consumption associated with the decreasing the charging current.

9. The method as claimed in claim 5, wherein the determining the heat generation amount comprises determining the heat generation amount based on the charging current, a resistance of the bus bar, and a duration of current flow.

10. The method as claimed in claim 5, wherein the determining the heat generation amount further comprises:
predicting a temperature change of the bus bar based on a mass of the bus bar and a heat capacity of the bus bar.

11. A method for controlling charging of a voltage distribution circuit, the method comprising:
setting a charging current for charging a battery;
setting a maximum charging current for charging the battery;
proceeding with charging the battery for a first cycle;
determining whether a state of charge (SOC) of the battery is satisfied;
determining whether a change of setting of the charging current occurs based on the SOC of the battery not being satisfied;
setting a cooling parameter based on the change of setting of the charging current occurring at a first time point, and measuring a temperature of a bus bar based on the change of setting of the charging current not occurring at a second time point; and
proceeding with charging the battery for a second cycle based on the measured temperature of the bus bar not reaching a threshold temperature at a third time point; and
proceeding with charging the battery for a third cycle by updating the cooling parameter based on the measured temperature reaching the threshold temperature at a fourth time point.

12. The method as claimed in claim 11, wherein the setting the cooling parameter comprises controlling to stop cooling of the bus bar.

13. The method as claimed in claim 11, wherein the updating the cooling parameter comprises controlling to increase cooling of the bus bar.

14. The method as claimed in claim 11, further comprising completing the charging after the SOC of the battery transitions from not being satisfied to being satisfied.

15. The method as claimed in claim 11, wherein the proceeding with charging the battery for the third cycle comprises increasing, based on the updated cooling parameter, cooling of the bus bar or decreasing the charging current.

16. The method as claimed in claim 11, wherein the proceeding with charging the battery for the third cycle comprises increasing cooling of the bus bar based on a first power consumption associated with the increasing the cooling being smaller than a second power consumption associated with decreasing the charging current.

17. The method as claimed in claim 11, wherein the proceeding with charging the battery for the third cycle comprises decreasing the charging current based on a first power consumption associated with increasing cooling of the bus bar being greater than a second power consumption associated with the decreasing the charging current.

18. The method as claimed in claim 11, further comprising:
determining a heat generation amount associated with the charging current.

19. The method as claimed in claim 18, further comprising:
increasing the charging current based on a charging time period not being satisfied and the heat generation amount being a threshold amount or below the threshold amount.

20. The method as claimed in claim 18, wherein the determining the heat generation amount comprises determining the heat generation amount based on the charging current, a resistance of the bus bar, and a duration of current flow.
